(19) United States
(12) Patent Application Publication
(10) Pub. No.: US 2019/0241086 A1
(43) Pub. Date: Aug. 8, 2019

(54) VEHICLE CHARGING STATION LOCATOR

(71) Applicant: Ford Global Technologies, LLC, Dearborn, MI (US)

(72) Inventors: Manuel Bojahr, Dormagen/NRW (DE); Heiko Maas, Aachen/NRW (DE); Michael Koherr, Euskirchen/NRW (DE); Dominik Pahlke, Cologne/NRW (DE)

(73) Assignee: Ford Global Technologies, LLC, Dearborn, MI (US)

(21) Appl. No.: 16/255,017

(22) Filed: Jan. 23, 2019

(30) Foreign Application Priority Data
Feb. 7, 2018 (DE) 102018201894.4

(51) Int. Cl. B60L 53/30; B60L 53/16; G01R 31/382; H04W 4/021; H04W 4/44; B60Q 1/04; G01C 21/36

(52) U.S. Cl. CPC B60L 53/305; B60L 53/16; G01R 31/382; B60L 2240/622; H04W 4/44; B60Q 1/04; G01C 21/3679; H04W 4/021

(57) ABSTRACT

A method for displaying charging stations for vehicles, wherein the vehicle comprises a navigation system for determining the current position of the vehicle, the location of the charging stations with which a vehicle battery of the vehicle may be charged being stored in said navigation system, and at least one headlight, comprises determining the current position of the vehicle and comparing the current position of the vehicle to the location of at least one of the stored charging stations by the navigation system and if the current position of the vehicle is within a selectable distance from the location of a charging station, activating the headlight with a pattern that may be selected.

### CROSS-REFERENCE TO RELATED APPLICATION

This patent application claims priority to German Application No. DE 102018201894.4 filed on Feb. 7, 2018, which is hereby incorporated by reference in its entirety.

### BACKGROUND

Charging stations with which it is possible to charge the vehicle battery that is used to store electrical energy are growing in importance with the increasing electrification of vehicle drive trains. Charging stations are in fact particularly important for electric vehicles for maintaining mobility, but it may also be necessary to charge a vehicle battery in the case of hybrid vehicles that also comprise an internal combustion engine in addition to the electric motor, said internal combustion engine being operated using an energy source in which chemical energy is stored. Energy sources of this type are in particular fossil fuels such as diesel or gasoline but also alternative fuels such as hydrogen. In general, these fuels are stored in fluid form and are burnt in fluid form in the internal combustion engine of the vehicle. Whilst energy sources of this type are only available in filling stations on account of it being necessary to store said energy sources in large tanks, in comparison charging stations with which the vehicle batteries may be charged require considerably less space than filling stations. On account of the fact that the space that is required is considerably reduced, there is the possibility of setting up charging stations away from filling stations, by way of example in a parking lot or parking garage of a supermarket. Whilst filling stations are visible from great distances on account of their size and in darkness are prominently illuminated, charging stations may only be poorly visible in particular in darkness or at dusk. As mentioned, charging stations may be set up in parking lots or parking garages where said charging stations are obscured by parked vehicles and may be barely visible to the driver.

U.S. Pat. No. 9,545,853 B1 discloses a charging station that comprises a highly visible display device that illuminates with a specific color depending upon the state of the charging station. If the charging station is vacant, the display device is illuminated in green, if the charging station is occupied, said display device is illuminated in red and if said charging station will shortly be vacant, said display device is illuminated in orange. A charging station that is embodied in this manner is available where multiple charging stations are set up next to one another similar to the fuel dispensers of a filling station. The display device assists the driver in this case to drive to the particular charging station that is vacant or would next be vacant. In the frequently occurring event of only one single charging station being set up, the color signal of the display device is frequently obscured in the plurality of other light sources that are arranged in the area and consequently only serves little use to the driver when identifying the charging station.

US 2015/0343912 A1 discloses a system that displays to the driver the optimal stopping position at a charging station in order to ensure that the plug of the vehicle may be reached using the cable length that is provided by the charging station. However, this system requires the driver to have already identified the charging station.

### SUMMARY

The present disclosure relates to a method for displaying or indicating charging stations for vehicles, in particular for electric vehicles, and to a vehicle that is embodied so as to implement a method of this type. Provided is a method for displaying charging stations for vehicles, said method making it easier for the driver to locate charging stations.

One embodiment relates to a method for displaying charging stations for vehicles, in particular for electric vehicles, wherein the vehicle comprises a navigation system for determining the current position of the vehicle, the location of the charging stations with which a vehicle battery of the vehicle may be charged being stored in said navigation system, and at least one headlight, wherein the method comprises the following steps:
determining the current position of the vehicle and comparing the current position of the vehicle with the location of at least one of the stored charging stations by means of the navigation system, and
if the current position of the vehicle is within a selectable distance from the location of a charging station, activating the headlight by means of a pattern that may be selected.

As mentioned above, it is difficult to locate charging stations, in particular at dusk or in darkness. The location of charging stations may in fact also be determined with the aid of the navigation system, however the directions from the navigation system may not be precise enough in order to direct the driver with sufficient accuracy to the charging station. Even if the navigation system tells the driver that the charging station is by way of example to the right-hand side or to the left-hand side of the vehicle, the driver may estimate poorly whether he must stop immediately or must drive a further 10 or 20 meters. In each case, the driver searches the area surrounding the vehicle and in so doing is distracted, which leads to the fact that he does not follow traffic events with the necessary degree of attention, which may result in accidents.

In accordance with the present disclosure, a headlight of the vehicle is used in addition, or as an alternative, to directions of the navigation system in order to assist the driver when locating the charging station. As a consequence, it is not necessary for the driver to direct his gaze away from the area ahead of the vehicle, with the result that he may further follow traffic events and is not distracted. Furthermore, headlights are particularly effective in darkness or at dusk in order to clearly direct the driver if said driver is within a selectable distance from the location of the charging station. In this case, the headlight may be activated with a pattern that may be selected in order to make the driver aware that he is near to a charging station. By way of example, the brightness of the headlight may be turned up and dimmed with a specific frequency. In this case, the frequency of turning up and dimming the brightness increases as the distance to the charging station reduces, and said frequency reduces as the distance increases. As a consequence, the driver receives a notification if he is in the immediate vicinity of the charging station and if he is getting further away from said charging station. In this case, the headlight is activated independently of whether the headlight is already switched on or not. If the headlight is switched on, it is only necessary to ensure that the headlight is activated in such a manner that it projects light in a manner that may be identified by the driver. It is clearly easier using the method in accordance with the present disclosure to locate the charging station, in particular at dusk and in darkness, and the danger of accidents as a result of the driver paying less attention to traffic events is reduced.

In accordance with a further embodiment, the method comprises the following steps:
if the current position of the vehicle is within a selectable distance from the location of a charging station, activating the headlight in such a manner that the charging station is illuminated.

It is already customary to only switch on some of the headlights if the steering wheel is rotated by more than a specific steering angle. For this purpose, the vehicles comprise by way of example a left-hand side-headlight and a right-hand side-headlight that project light clearly more to the side than the main-headlight. The lateral area surrounding the vehicle may be illuminated using these lights in the case of large steering angles. These side-headlights may be used for this purpose in order to illuminate the charging station, as a result of which said charging station may be more visible for the driver and therefore easier to locate.

In a further-developed embodiment, the headlight may produce a cone of light, the orientation of which may be changed, wherein the method comprises the following step:
if the current position of the vehicle is within a selectable distance from the location of a charging station, changing the orientation of the cone of light in such a manner that the charging station is illuminated.

The cone of light from headlights that are presently known may be changed in an expedient manner in order to avoid by way of example dazzling the drivers of oncoming vehicles. Headlights of this type may be controlled in such a manner that they illuminate the charging station. It is considerably easier for the driver to locate the charging station on account of the charging station being illuminated.

In another embodiment, the cone of light may project symbols onto the ground or another illuminated surface and the method comprises the following step:
if the current position of the vehicle is within a distance, that may be selected, from the location of a charging station, producing symbols that point to the charging station or that display the way to the charging station.

Depending upon the embodiment of the headlight, said headlight is capable of projecting symbols onto the road or onto other surfaces of objects in the area surrounding the vehicle. By way of example, headlights may project arrows onto the road that indicate the location of the charging station to the driver. As a consequence, the procedure of locating the charging stations is easier without the driver having to divert his gaze from traffic events.

In a further embodiment, the charging station may comprise a state determining device, which may be used to determine the present state of the charging station, and a transmitting device, which may be used to transmit the present state to the vehicle and the method may comprise the following step:
producing symbols that point to the charging station or that display the way to the charging station that is in a state that renders it possible to charge the vehicle battery.

If the driver has found the charging station, it is possible however that said charging station is occupied. Information regarding the present state of the charging station is provided by means of the state determining device and the transmitting device. If the next charging station is presently occupied, the symbols may be selected in such a manner that they point to a further charging station that is presently vacant. If no further charging station is vacant in the surrounding area, the symbols may point to a waiting place where it is possible to wait until the charging station is vacant again. As a consequence, it is prevented that the driver is unnecessarily directed to a non-usable charging station and that time and energy, in particular electrical or chemical energy, are wasted. A “charging station management procedure” may also be simultaneously operated with the result that the charging stations that are provided are used as uniformly as possible and queues for frequently used charging stations are reduced and idle times are reduced at the less frequently used charging stations.

In accordance with a further embodiment of the method, the charging station comprises a position transmitter with which it is possible to transmit the location of the charging station to the navigation system, wherein the method comprises the following steps:
transmitting the location of the charging station by means of the position transmitter to the navigation system.

Although navigation systems may determine the current position of the vehicle with a relatively high degree of accuracy and consequently may also accordingly accurately determine the distance from the location of the charging station, there is however a certain inaccuracy depending upon the system used. Moreover, it is not always ensured that a position signal, by way of example a GPS signal, is available at the location of the charging station. In this embodiment of the method in accordance with the present disclosure, the position transmitter transmits the precise details of the location of the charging station to the navigation system that may determine therefrom the relative position of the vehicle in relation to the charging station independently of the availability by way of example of a GPS signal and consequently may display to the driver where the charging station is located. In this embodiment, it is also then rendered possible to locate the charging station if a GPS signal or a similar position signal is not available. The signal that is transmitted by the position transmitter may also include information regarding the present state of the charging station with the result that the navigation system only guides the driver to such charging stations that are in a state that renders it possible to charge the vehicle battery or that are soon to become vacant.

In a further embodiment, the vehicle may comprise a measuring device for measuring the state of charge of the vehicle battery and the method may comprise the following steps:
measuring the state of charge of the vehicle battery by means of the measuring device, and
performing the steps according to any one of the preceding embodiments if the state of charge falls below a value that may be predetermined.

In this embodiment, the driver is only guided to a charging station if the state of charge of the vehicle battery falls below a value that may be predetermined. In particular, in the case of electric vehicles, a sufficient state of charge is of the utmost importance in order to maintain mobility. In this respect, the driver is automatically guided using the above method steps to the charging station if the state of charge falls below a predetermined value. This value may be set by the driver themselves when configuring their vehicle or said value may be set in the factory. Since at the priority date of the present application the concentration of charging stations is comparatively low, the value that may be predetermined may also be determined by the navigation system itself in order to ensure that the next charging station may be safely reached without the vehicle battery completely draining prior to arrival and the vehicle breaking down.

One embodiment is characterized by the fact that the vehicle comprises a speed measuring device for determining the vehicle speed and the method comprises the following steps:
measuring the vehicle speed by means of the speed measuring device, and
performing the steps according to any one of the preceding embodiments if the vehicle speed falls below a value that may be predetermined.

As mentioned in the introduction, the charging stations are typically located on parking lots or in parking garages where the vehicle may only be moved at a low speed. However, it may be that in spite of this the driver approaches the charging station at too high a speed which may indicate that the driver for some reason does not want to use this charging station for the purpose of charging the vehicle battery. If the speed is too high, activating the headlight by means of a pattern that may be selected, by way of example by means of a cone of light that is oriented toward the charging station, may pose a risk to traffic safety. In order to prevent this, in this embodiment the headlight is only used to locate the charging station if the speed falls below a value that may be predetermined.

One embodiment relates to a vehicle, in particular a motor vehicle, which is embodied so as to implement the method according to any one of the preceding embodiments. The technical effects and advantages that may be achieved using the vehicle in accordance with the present disclosure correspond to the effects and advantages that have been discussed for the present method. In summary, reference is made to the fact that locating charging stations that are sometimes poorly visible and may be obscured by other vehicles is made considerably easier in particular in darkness and at dusk. Moreover, the directions to the charging station, said directions being issued by the headlight, barely distract the driver from traffic events, with the result that the search for the charging station does not lead to an increased risk of accident.

### SUMMARY OF THE DRAWINGS

Exemplary embodiments of the invention are explained in more detail below with reference to the attached drawings. In the drawings:

FIG. 1 illustrates a basic plan view of a first exemplary embodiment of a vehicle that may be operated using a disclosed method;

FIG. 2 illustrates a basic plan view of a second exemplary embodiment of a vehicle that may be operated using a disclosed method; and

FIG. 3 illustrates a basic plan view of a third exemplary embodiment of a vehicle that may be operated using a disclosed method.

### DESCRIPTION

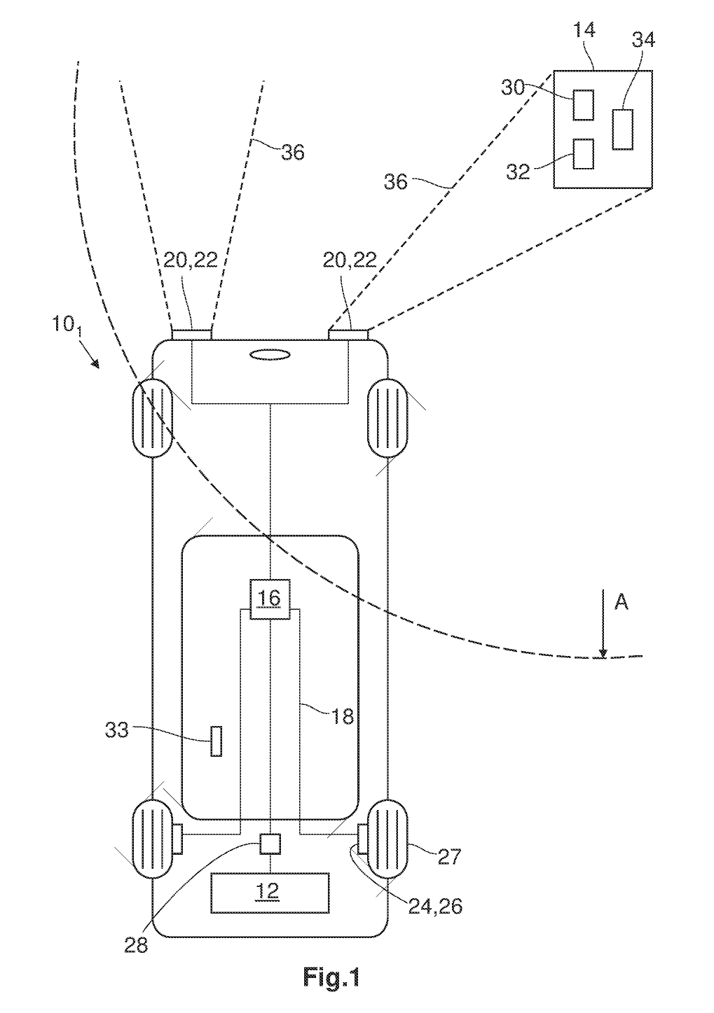

FIG. 1 illustrates a first exemplary embodiment of a vehicle 101 with reference to a basic plan view and said vehicle may be operated according to the disclosed method. The vehicle 101 may be an electric vehicle having an electric vehicle (not illustrated) but also said vehicle may be a vehicle 101 having an internal combustion engine that is likewise not illustrated. In both cases, the vehicle 101 comprises a vehicle battery 12 in which it is possible to store the electrical energy that is required to operate power units (not illustrated), by way of example the electric motor, and to operate electronic components. The vehicle battery 12 may be charged by means of a charging station 14, by way of example via a plug-socket cable connection that is not illustrated.

The vehicle 101 comprises a navigation system 16 with which it is possible to determine the current position of the vehicle 101. The navigation system 16 simultaneously also assumes open-loop control functions for implementing the method in accordance with the present disclosure, with the result that the navigation system 16 also comprises an open-loop control unit that is not illustrated separately. The navigation system 16 also uses map material on which the location of the charging station 14 is stored. The navigation system 16 is supplied with electrical energy from the vehicle battery 12, and electrical lines 18 are provided for this purpose.

Furthermore, the vehicle 101 according to the first exemplary embodiment comprises two headlights 20 that are embodied as front-headlights 22. The headlights 20 are connected via electrical lines 18 to the navigation system 16 and may be controlled by the navigation system 16 that is further explained below.

Moreover, the vehicle 101 comprises a speed measuring device 24 with which it is possible to determine the speed of the vehicle 101. The speed measuring device 24 comprises two rotary encoders 26 that are arranged respectively on a wheel 27 of the vehicle 101 and that may determine the rotational speed of the wheels. The signals that are generated by the rotary encoders 26 are relayed via electrical lines 18 to the navigation system 16.

Furthermore, the vehicle 101 comprises a measuring device 28 for measuring the state of charge of the vehicle battery 12. The signals that are generated by the measuring device 28 are also relayed to the navigation system 16.

The charging station 14 is fitted with a state determining device 30 that may determine the state of the charging station 14. The state of the charging station 14 comprises in particular the functionality of the charging station 14. Moreover, the state includes whether the charging station 14 is vacant or if it is occupied and if it is occupied, how long it will take until the charging station 14 becomes vacant again. Furthermore, the charging station 14 comprises a transmitting device 32 with which the states of the charging station 14 that are determined by the state determining device 30 may be transmitted to the vehicle 101 and in particular to the navigation system 16. The vehicle 101 is fitted with an antenna 33 that may be used to receive by way of example GPS signals. This antenna 33 may be used to receive signals that are transmitted by the transmitting device 32.

Furthermore, the charging station 14 comprises a position transmitter 34 that transmits details regarding the location of the charging station 14 to the navigation system 16. In this case, the already mentioned antenna 33 of the vehicle 101 may also be used to receive the signals that are related to the location of the charging station 14, said signals being transmitted by the position transmitter 34.

The vehicle 101 according to the first exemplary embodiment may be operated by way of example in the following manner:

Whilst driving, the measuring device 28 determines that the state of charge of the vehicle battery 12 has fallen below a predetermined value and that the vehicle battery should be charged so as to maintain mobility. The navigation system 16 determines in this case the location of the closest charging station 14 and checks with reference to the signals of the state determining device 30 whether the charging station 14 is in operation and may be used to charge the vehicle battery 12. If this is the case, the navigation system 16 guides the driver to said charging station. The navigation system 16 may provide a corresponding notification to the driver with the result that the driver is not irritated by the fact he is directed to a destination that deviates from the destination that is input.

The navigation system 16 compares the current position of the vehicle 101 with the location of the charging station 14. If the vehicle 101 has approached the charging station 14 at a predetermined distance, by way of example 2 km (kilometers), the navigation system 16 checks the state of the charging station 14 for whether the charging station 14 is vacant or is not. If the charging station 14 is currently occupied, the navigation system 16 may direct the driver to a vacant charging station 14 that is situated nearby. If a further charging station 14 is not present in the area, the navigation system 16 indicates to the driver an expected waiting time and directs him to a waiting area.

If the charging station 14 is vacant and the vehicle 101 approaches the charging station 14 at a specific distance A, by way of example 100 m (meters), the navigation system 16 thus checks with reference to the signals of the speed measuring device 24 whether the vehicle 101 is travelling slower than a speed that may be predetermined, by way of example slower than 30 km/h. If this is the case, the navigation system 16 activates at least one of the headlights 20 by means of a pattern that may be predetermined, in order to alert the driver to the fact that he has reached the charging station 14. By way of example, the navigation system 16 may turn up the brightness of the headlights three times.

The front-headlight 22 of the vehicle 101 according to the first exemplary embodiment produces a changeable cone of light 36. In addition to turning up the headlights, the cone of light 36 may be changed in such a manner that it is oriented to the charging station 14 and illuminates said charging station as illustrated in FIG. 1. As a consequence, the charging station 14 may be particularly easily identified, in particular at dusk or in darkness. In FIG. 1, only the cone of light 36 of the right-hand headlight of the two front-headlights 22 is oriented to the charging station 14 whilst the cone of light 36 of the left-hand front-headlight 22 remains unchanged.

As mentioned, the charging station 14 is fitted with the position transmitter 34. The position transmitter 34 transmits details regarding the location to the navigation system 16, by way of example the coordinates. The navigation system 16 may itself perform a procedure of determining the position of the vehicle 101 in relation to the charging station 14 using the signal that is transmitted by the position transmitter 34. The GPS signal has a certain inaccuracy with the result that the headlight 20 could be activated too far ahead of or behind the charging station 14 and consequently may only partially aid the driver when locating the charging station 14. In particular if the cone of light 36 is to be oriented at the charging station 14, a particularly precise knowledge of the position of the vehicle 101 in relation to the charging station 14 is necessary. The position of the vehicle 101 in relation to the charging station 14 may be determined with the required accuracy using the position transmitter 34. Moreover, the position of the vehicle 101 in relation to the charging station 14 may then also be determined if the GPS signal cannot be received.

During the course of efforts to prepare vehicles 101 for autonomous driving, the vehicles 101 are fitted with various types of monitoring devices in order to be able to monitor the area surrounding the vehicles 101. By way of example, vehicles of this type comprise cameras, laser scanners, ultrasonic and/or radar capabilities. The charging station 14 may be fitted as such and/or the position transmitter 34 may be fitted in such a manner that said charging station may be readily identified by said monitoring devices as a charging station 14 or being associated with a charging station 14. The position of the vehicle 101 in relation to the charging station 14 may be determined therefrom with a sufficient accuracy independently of the navigation system 16 as soon as the vehicle 101 is located within a specific distance A with respect to the charging station 14.

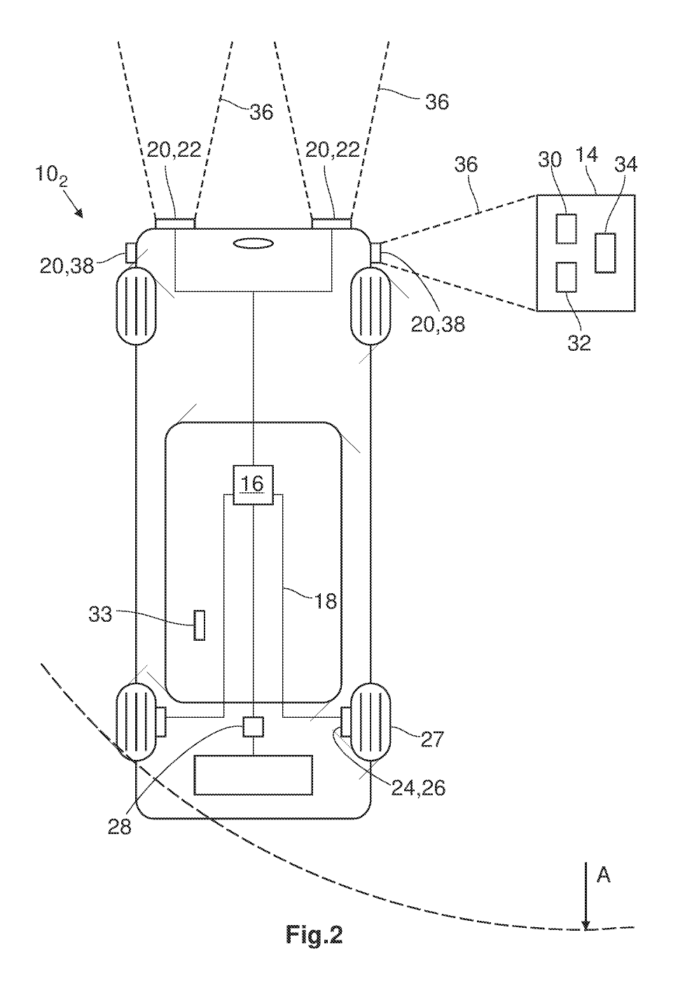

FIG. 2 illustrates a second exemplary embodiment of the vehicle 102 with reference to a basic plan view and said vehicle may be operated according to the method. The fundamental construction of the vehicle 102 according to the second exemplary embodiment corresponds to that of the vehicle 101 according to the first exemplary embodiment. The vehicle 102 according to the second exemplary embodiment is essentially also operated in the same manner as the vehicle 101 according to the first exemplary embodiment. However, the vehicle 102 according to the second exemplary embodiment also comprises, in addition to the front-headlights 22, a left-hand and a right-hand side-headlight 38, that are typically then activated if the steering wheel is rotated particularly intensely, which by way of example is the case if the driver wants to turn from a road into a road that is branching off. The relevant side-headlight 38 illuminates the region of the road that is branching off and which is not illuminated by the front-headlights 22.

In the vehicle 102 according to the second exemplary embodiment, the side-headlights 38 are used in order to illuminate the charging station 14 and thus to facilitate the driver locating the charging station. The side-headlights 38 are then activated if their cone of light 36 may illuminate the charging station 14. In the second exemplary embodiment, the vehicle 102 does not require front-headlights 22 that are capable of changing their cone of light 36.

Typically, vehicles that comprise a front-headlight 22 that may change their cone of light 36 are also fitted with a side-headlight 38. In this case, it is possible both to orient the cone of light 36 of at least one front-headlight 22 to the charging station 14 as well as to illuminate the charging station 14 with the side-headlight 38. This is in particular therefore expedient because the cone of light 36 of the front-headlight 22 may not be oriented arbitrarily to the side of the vehicle 101. If the vehicle 102 is in the position that is illustrated in FIG. 2, it is no longer possible or it is only very conditionally possible to illuminate the charging station 14 using the front-headlight 22. In this respect, the illumination of the charging station 14 using the side-headlights 38 as illustrated in FIG. 2 may be preceded by an illumination using the changeable cone of light 36 of the front-headlight 22, as illustrated in FIG. 1.

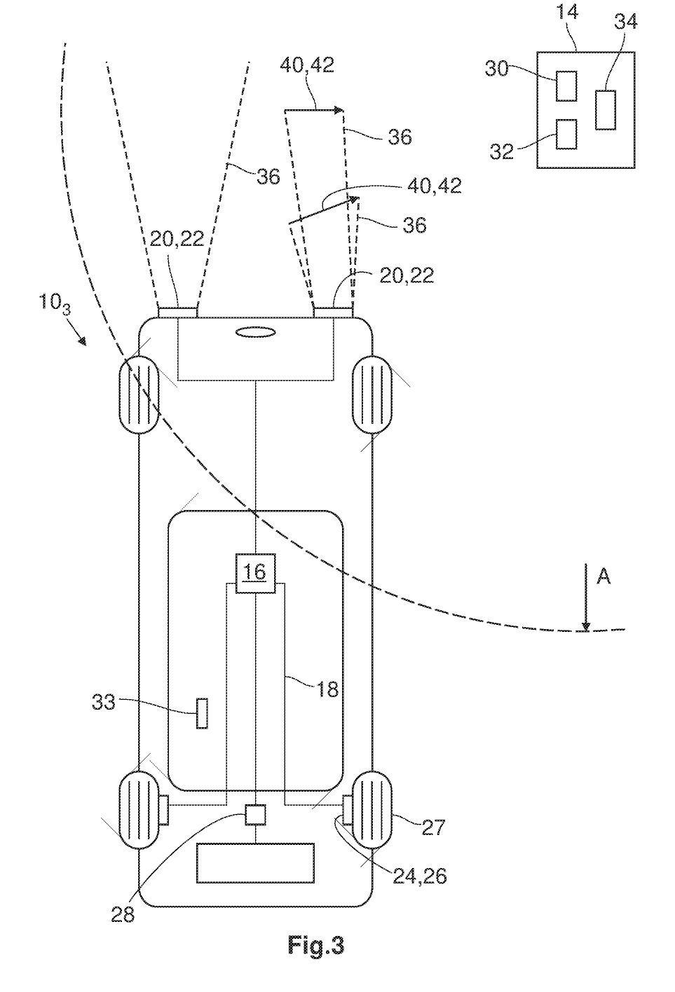

FIG. 3 illustrates a third exemplary embodiment of the vehicle 103 with reference to a basic plan view and said vehicle may be operated according to the method. The fundamental construction of the vehicle 103 according to the third exemplary embodiment corresponds to that of the vehicle 101 according to the first exemplary embodiment. The vehicle 103 according to the third exemplary embodiment is essentially operated in the same manner as the vehicle 101 according to the first exemplary embodiment. However, the front-headlights 22 are embodied in this case in such a manner that they may project symbols 40 onto the road or another surface, in this case arrows 42 that point toward the charging station 14. The arrows 42 may be adjusted in their orientation with the changing position of the vehicle 101 in relation to the charging station 14, as illustrated in FIG. 3.

### LIST OF REFERENCE NUMERALS

10, 101 to 103 Vehicle
12 Vehicle battery
14 Charging station
16 Navigation system
18 Electrical lines
20 Headlight
22 Front-headlight
24 Speed measuring device
26 Rotary encoder
27 Wheel
28 Measuring device
30 State determining device
32 Transmitting device
33 Antenna
34 Position sensor
36 Cone of light
38 Side-headlight
40 Symbol
42 Arrow
A Distance

1-9. (canceled)

10. A method, comprising:
determining a current position of a vehicle via a navigation system in the vehicle;
comparing the current position of the vehicle with a stored location of a charging station; and
upon determining that the current position of the vehicle is within a threshold distance from the stored location of the charging station, activating a headlight of the vehicle according to a pattern selected to indicate the stored location.

11. The method of claim 10, further comprising activating the headlight in a manner such that the charging station is illuminated.

12. The method of claim 10, wherein the headlight is configured to produce a cone of light, the method further comprising changing an orientation of the cone of light in a manner such that the charging station is illuminated.

13. The method of claim 10, wherein the headlight is configured to produce a cone of light that projects a symbol, the method further comprising activating the light to project a symbol that points to the charging station.

14. The method of claim 10, further comprising:
receiving a transmission from the charging station specifying a present state of the charging station; and
selecting the charging station to be indicated by the headlight upon determining that the present state renders the charging station able to charge a vehicle battery.

15. The method of claim 10, further comprising receiving a transmission from the charging station specifying the location of the charging station.

16. The method of claim 10, further comprising:
measuring a state of charge of a vehicle battery; and
comparing the current position of the vehicle with the stored location of the charging station upon determining that the state of charge is below a predetermined threshold.

17. The method of claim 10, further comprising:
measuring a vehicle speed; and
comparing the current position of the vehicle with the stored location of the charging station upon determining that the vehicle speed is below a predetermined threshold.

18. A vehicle system, comprising programming to:
determine a current position of a vehicle via a navigation system in the vehicle;
compare the current position of the vehicle with a stored location of a charging station; and
upon determining that the current position of the vehicle is within a threshold distance from the stored location of the charging station, activate a headlight of the vehicle according to a pattern selected to indicate the stored location.

19. The system of claim 18, further comprising programming to activate the headlight in a manner such that the charging station is illuminated.

20. The system of claim 18, wherein the headlight is configured to produce a cone of light, the system further comprising programming to change an orientation of the cone of light in a manner such that the charging station is illuminated.

21. The system of claim 18, wherein the headlight is configured to produce a cone of light that projects a symbol, the system further comprising programming to activate the light to project a symbol that points to the charging station.

22. The system of claim 18, further comprising programming to receive a transmission from the charging station specifying a present state of the charging station; and
select the charging station to be indicated by the headlight upon determining that the present state renders the charging station able to charge a vehicle battery.

23. The system of claim 18, further comprising programming to receive a transmission from the charging station specifying the location of the charging station.

24. The system of claim 18, further comprising programming to:
determine a state of charge of a vehicle battery; and
compare the current position of the vehicle with the stored location of the charging station upon determining that the state of charge is below a predetermined threshold.

25. The system of claim 18, further comprising programming to:
determine a vehicle speed; and
compare the current position of the vehicle with the stored location of the charging station upon determining that the vehicle speed is below a predetermined threshold.
